(19) United States
(12) Patent Application Publication
(10) Pub. No.: US 2008/0157455 A1
(43) Pub. Date: Jul. 3, 2008

(54) COMPLIANT SUBSTRATE HOLDING ASSEMBLY

(75) Inventors: PAUL E. LESTER, Emmett, ID (US); Anthony J. Senn, Nampa, ID (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/617,831

(22) Filed: Dec. 29, 2006

(51) Int. Cl. H01L 21/683

(52) U.S. Cl. 269/287

(57) ABSTRACT

Methods and apparatus for holding substrate in a compliant substrate holding assembly are provided. In one embodiment, an apparatus for a compliant substrate holding assembly includes a base plate, a finger disposed on the base plate having a V-shaped slot formed thereon, and two arms disposed on opposite ends of the base plate and each arm having V-shaped slot formed therein. In another embodiment, a method for holding a substrate on a compliant substrate holding assembly includes inserting a substrate into a holding assembly having at least three substrate supporting members and detecting a change in position of one of the substrate supporting structures.

### BACKGROUND OF THE INVENTION

1. Field of the Invention

Embodiments of the invention generally relate to a method or an apparatus for holding a semiconductor substrate.

2. Description of the Related Art

Integrated circuits have evolved into complex devices that can include millions of components (e.g., transistors, capacitors and resistors) on a substrate (e.g., semiconductor wafer). Millions of micro-electronic field effect transistors (e.g., complementary metal-oxide-semiconductor (CMOS) field effect transistors) that are formed on the substrate and cooperate to perform various functions within the circuit. Typically, thousands of or even more process steps are performed to form the components on the substrate. During device manufacturing, it is occasionally necessary to hold one or more substrates in a vertical orientation during and/or between process steps. For example, a substrate holding assembly may be used in a measuring system to provide a transfer platform for staging substrates prior to and/or after inspection. In another example, a substrate holding assembly may be used in a wet clean system to provide a platform on which multiple substrates. Examples of processes that may need and use substrate holding assemblies include wet bench processing systems, dry cleaning processing systems, ion implanting process, photomask manufacturing process, and other different types of semiconductor processing systems.

FIG. 1A depicts an exemplary substrate holding assembly 100 that may hold one or more substrates. The substrate holding assembly 100 includes a base plate 102 having slots 104 formed therein. Each slot 104 is configured to receive a substrate 106. As shown in an enlarged view of the base plate 102 depicted in FIG. 1B, a thru-beam or reflectance sensor 108 may be mounted or embedded within the base plate 102 to detect the presence of the substrate 106 in the slot 104 of the substrate holding assembly 100. As the substrate 106 may be opaque or transparent, the sensor 108 may not reliably detect the substrate.

FIG. 2 depicts a sectional view of the slot 104 formed in the base plate 102. A channel 202 is formed and extended from a bottom apex of the slot. The channel 202 receives a bottom end portion of the substrate 106 such that the substrate 106 is held vertically in the channel 202. However, as the channel 202 must be wide enough to accommodate different substrate thickness, thinner substrates may lean away from vertical when placed in the channel 202. The leaning substrates may contact neighboring substrates positioned in the base plate 102, thus resulting in damage, contamination, and/or scratching. Additionally, leaning substrates may interfere with substrate transfer or result in collision between substrates during robot transfer.

Therefore, there is a need for an improved substrate holding assembly.

### SUMMARY OF THE INVENTION

Methods and an apparatus for holding substrate are provided. In one embodiment, an apparatus, such as a compliant substrate holding assembly, includes a base plate, a finger disposed on the base plate having a substrate receiving slot and two arms disposed on opposite end of the base plate, and each arm having a substrate receiving slot formed therein.

In another embodiment, a compliant substrate holding assembly includes a substrate supporting structure biased to a first position above a base plate and a sensor arranged to detect a change in position of the substrate supporting structure.

In yet another embodiment, a compliant substrate holding assembly includes a base plate having at least two arms extending upward from opposite sides of the base plate, a resilient finger disposed between the arms, and a sensor arranged to detect a change in position of the finger.

In still another embodiment, a method for holding a substrate on a compliant substrate holding assembly includes providing a substrate supporting structure having a finger disposed on a base plate, setting a substrate on the substrate supporting structure, and detecting a change in position of the finger.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1B depict perspective views of a conventional substrate holding assembly;

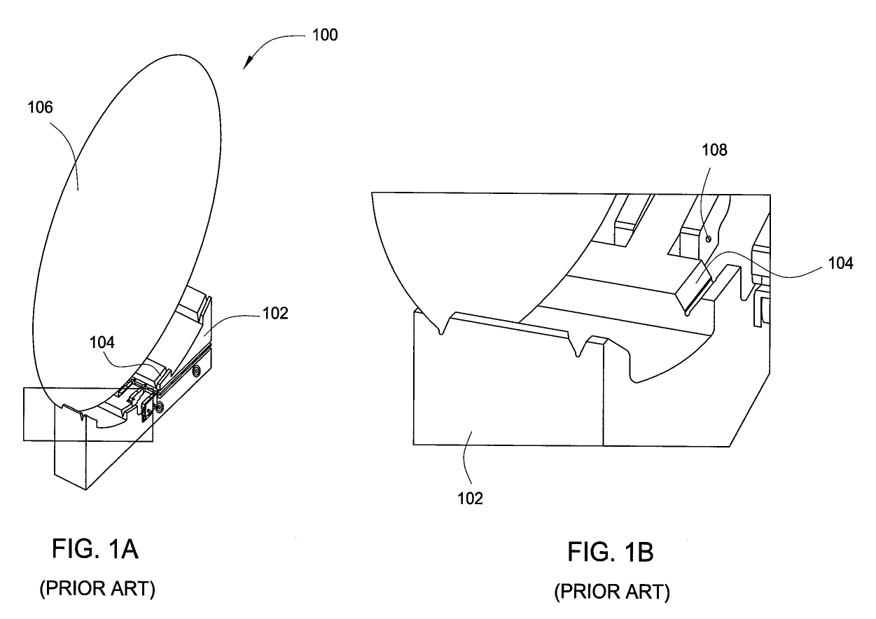

FIG. 2 depicts cross sectional view of a conventional substrate holding assembly;

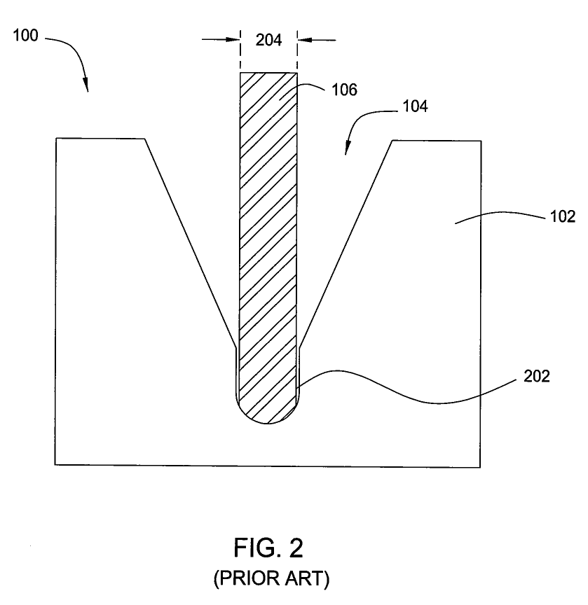

FIG. 3 depicts a perspective view of one embodiment of a substrate holding assembly according to the present invention;

FIG. 4 depicts an exploded view of a substrate holding assembly of FIG. 3;

FIG. 5 depicts a side view of the substrate holding assembly of FIG. 3;

FIG. 6 depicts a partial side view of the substrate holding assembly of FIG. 3 having a substrate positioned thereon; and

FIG. 7 depicts a partial sectional view of one embodiment of a V-shaped slot formed in the substrate holding assembly of FIG. 4.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides a method and an apparatus for holding a substrate in a vertical orientation. In one embodiment, the substrate holding assembly has a substrate supporting structure that moves to accommodate substrates of various dimensions and materials, thereby substantially preventing substrate improper positioning, misalignment, and substrate lean. The substrate holding assembly provides three substrate contact points. In another embodiment, a sensor may be provided to accurately detect the presence of a substrate in the holding assembly. The presence of the substrate may be triggered by a change in position of a structure that supports the substrate. Since the change in position of the substrate supporting structure is indicative of the presence of the substrate in the substrate holding assembly, opaque or transparent substrates may be reliably detected.

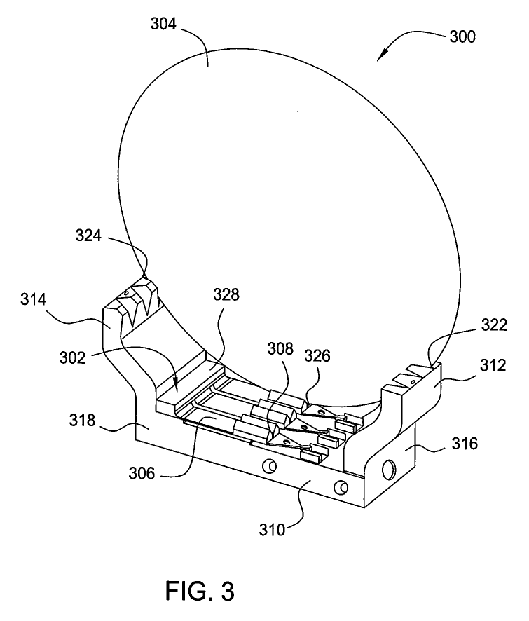

FIG. 3 depicts a perspective view of a substrate holding assembly 300 according to one embodiment of the present invention. The substrate holding assembly 300 includes a substrate supporting structure 302 disposed on a base plate 310. The substrate supporting structure 302 allows the substrates being placed in the assembly 300 to be maintained in a parallel and spaced apart relation. The base plate 310 has a first end 316, a second end 318, and an upper surface 320. Two arms 312, 314 extend from opposite ends 316, 318 of the base plate 310. The substrate supporting structure 302 is disposed on the upper surface 320 of the base plate 310 in a cantilevered orientation. The arms 312, 314 each have a substrate receiving slot 322, 324. In one embodiment, the slots 322, 324 are arranged around the 3 and 9 o'clock positions. The substrate supporting structure 302 supports the substrate 304 at a third substrate receiving slot below the substrate. The two upper slots 322, 324 along with the third slot 326 in the substrate supporting structure 302 defines a plane in which the substrate 304 is securely upheld in the assembly 300.

The substrate supporting structure 302 moves to accommodate substrates 304 having different thicknesses and diameters while maintaining the substrate securely in a vertical orientation within the assembly 300. In one embodiment, the base plate 310, the substrate supporting structure 302 and the two arms 312, 314 may be fabricated by a plastic material, such as perfluoroalkoxy (PFA), Telfon®, polyetherimide, Ultem®, or other suitable materials. In another embodiment, the assembly 300 may be fabricated by other suitable types of ceramic, metal or polymer materials.

In embodiment where the substrate holding assembly 300 is fabricated by a conductive material, such as metals, an electrically conductive ground path may be provided to eliminate static electricity from building on the assembly 300 or substrates positioned therein. The conductive ground path may be created by utilizing a conductive material, such as foils, wires, connecting the substrate holding assembly 300 at a first end and routing to the ground at a second end. In one embodiment, the conductive material may have a first end coupled to the base plate 310, the substrate supporting structure 302, the two arms 312, 314, or other suitable location in the substrate holding assembly 300 and a second end routed to the ground.

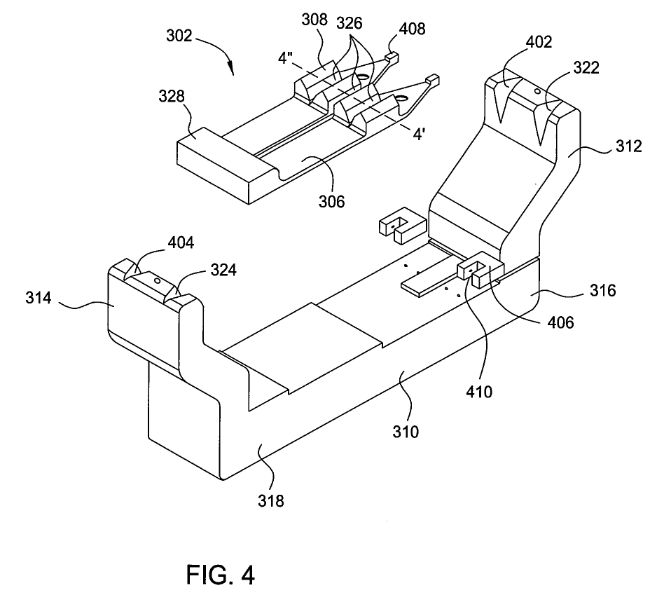

In one embodiment, the substrate supporting structure 302 includes a plurality of fingers 306 configured to hold separate substrates. Each finger 306 extends from a body 328 to form a comb-like structure. FIG. 4 depicts an exploded view of the substrate supporting structure 302 and the base plate 310. The body 328 is coupled to the second end 318 of the base plate 310 proximate the bottom portion of the second arm 314. Each finger 306 has a substrate receiving slot 308. The slot 308 may be defined between elements 326 extending above the finger 306. The body 328 is coupled to the base plate 310 so that each finger 306 is suspended above the base plate 310 in a cantilevered orientation. As the finger 306 may deflect downward under the weight of the substrate set thereon, the geometry between the three slots 322, 324, 308 that support the substrate automatically accommodates substrates of different diameters. Each finger 306 is in a spaced-apart relationship to one another, thereby allowing each finger 306 to move independently. The distance between the fingers 306 is selected to prevent substrates supported on each finger 306 from colliding during transfer by robotic mechanism. The slot 308 may be in the form of a V-shaped or other suitable profile as to permit engagement of a single substrate. The dimension of the slot 308 is machined and sized to allow substrates with various thicknesses at a selected range to be supported and fit therein vertically.

A tip 408 is formed on a distal end of the finger 306. A sensor 406 is disposed proximate to the first end 312 of the base plate 310 and has a notch 410 configured to allow the tip 408 to pass therethrough upon deflection of the finger 306. The sensor 406 provides a light beam transmitting across the notch 410 which detects the presence of the tip 408, which corresponds to the presence of the substrate. Other sensors suitable for detecting the change in position of the tip 408 due to deflection of the finger 306 may be utilized. Since the sensor 406 is triggered by the change in position of finger 306 due to the substrate, the sensing mechanism is insensitive to materials of the substrate 304, and as such, the presence of transparent and other hard to detect substrates may be reliably sensed in the assembly 300.

The arms 312, 314 and support structure may have additional slots 402, 404 formed therein to hold additional substrates. Although the assembly 300 is shown configured to hold two substrates, it is contemplated that the assembly may be configured to hold any number of substrates.

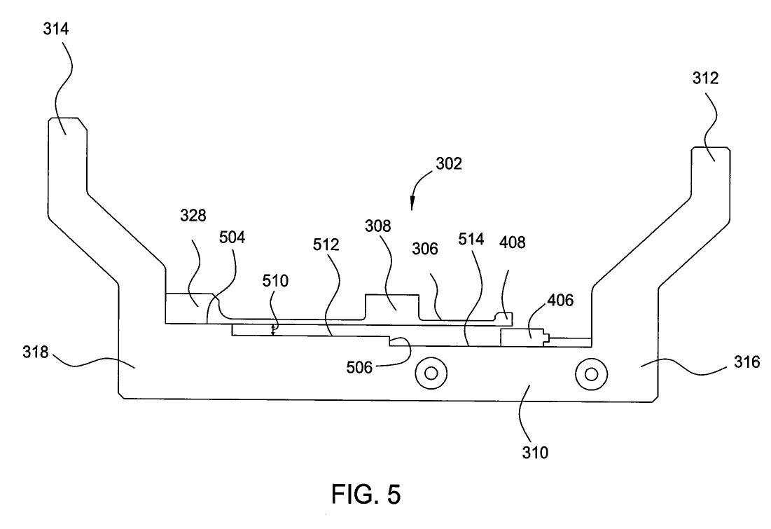

FIG. 5 depicts a side view of the substrate holding assembly 300 having the substrate supporting structure 302 disposed thereon. A first step 504 may be formed proximate the bottom portion of the second arm 314 and on the second end 318 of the base plate 310. The body 328 of the substrate supporting structure 302 is disposed on an upper surface of the first step 504. As the finger 306 is coupled to the body 328 and has a length extending toward the first end 316 of the base plate 310, a gap 510 is defined between the finger 306 and an upper surface 512 of the base plate 310. The gap 510 allows the finger 306 to deflect downward from the body 328 toward the base plate 310 under the weight of the substrate. A second step 506 may be formed in the middle section of the base plate 310 underneath the location where the slot 308 is formed on the finger 306. The second step 506 is configured to prevent the finger 306 from bending too far which may result in finger breakage or change in the spring constant of the finger. The second step 506 also allows the tip 408 of the finger 306 to travel toward the lower base plate surface 514 and engage the sensor 406. The finger 306 performs as a leaf spring, providing a spring suspension that holds each individual substrate in the slot 308. The position of the tip 408 within the notch 410 allows a flag disposed on the tip 408 to cause the state of the sensor 406 to change in a consistent and reliable manner, thereby providing an accurate detection of the substrate within the holder assembly 300.

The flexible and compliant character of the finger 306 provides a compensation and accommodation for multiple sources of substrate misalignment including from parts tolerances, assembly error, substrate warping due to age or thermal expansion, or dimension variation. The compliant finger 306 also acts to reduce the forces applied to the substrate during transfer from a cassette (e.g., FOUP) to the substrate supporting structure 302 or from the substrate supporting structure 302 to a processing station.

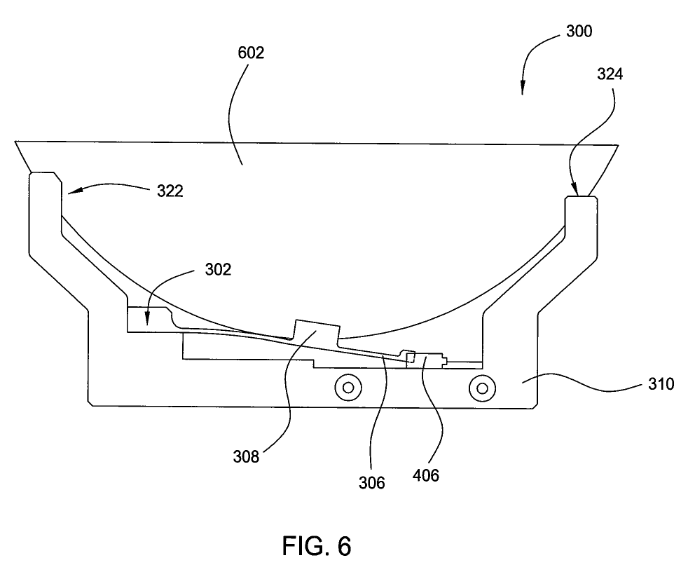

FIG. 6 depicts a sectional view of the substrate holding assembly 300 having a substrate 602 positioned on the substrate supporting structure 302. As the substrate 602 is inserted into the assembly, the substrate 602 rests in the slot 308 formed on the finger 306. The spring force of the finger 306 cushions the placement of the substrate 602 into the holding assembly 300, thereby reducing substrate damage. Furthermore, the resilience of the finger 306 allows the finger 306 to deflect under the weight of the substrate 602, which causes the tip 408 to trigger the sensor 406, thereby indicating the presence of the substrate 602 in the holding assembly 300.

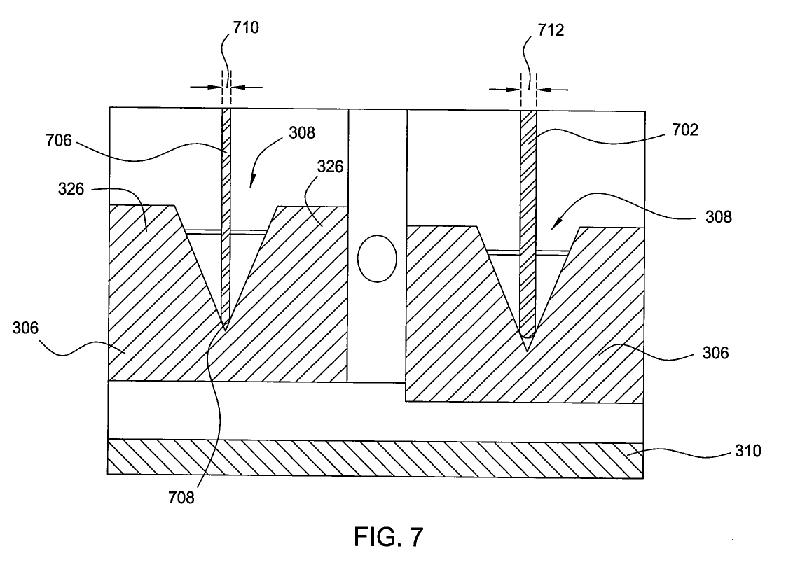

FIG. 7 depicts a sectional view of one embodiment of the V-shaped slot 308 disposed on the finger 306 along with the cutting line of 4′-4″ as shown in FIG. 4. The slot 308 is V-shaped meaning the slots are configured so that the substrate rests on the sides of the “V.” As the substrate may have different thickness and diameters, the third contact point within the slot 308 may be slightly varied. For example, as a substrate 706 having a thinner thickness 710 inserting into the slot 308, the bottom edge 708 of the substrate 706 may ride over the slot 308 at a deeper point within the slot 308 as compared to a substrate 702 having a thicker thickness 712 shown in an adjacent slot 308. The wider thickness 702 prevents the substrate 702 from going as deep into the slot as that of the thinner substrate 706. Moreover, if the thicker substrate 702 has a slightly greater diameter than the thinner substrate 706, the finger 302 supporting the larger diameter substrate 702 may move closer to the base plate 310.

The V-shaped configuration of the slot 308 formed on the finger 306 along with the V-shaped slots 402, 404 formed in the two arms 314, 312 provides a stable and adjustable contact points to accommodate the substrate with different dimensions positioned within the slots. As the substrates with different thickness may rest on the finger 306 with different third contact points (e.g., higher or lower contact points within the slot 308) at and around substrate's 6 o'clock position, the two substrate edges at its 3 and 9 o'clock position in contact with the slots on the arms may create different first and second contact points as well. The V-shaped configuration of the slots 308, 322, 324 enables the substrate being placed in the slots to have three contact points. The three contact points provide a secure and stable position that allows the substrate to be in place within the substrate supporting structure 302 without leaning forward or backward from the vertical plane, thereby efficiently preventing and reducing the cross-substrate damage or misplacement. The V-shaped configuration of the slots accommodate and compensate substrates with dimension variation to be upstraightly held thereupon and allows the substrates to touch the V-shaped configuration at different contact points with different depth within the slots.

Thus, methods and apparatus for holding substrate in a substrate holding assembly are provided. The compliant structure formed in the substrate holding assembly advantageously provides compliance or flexible motion to substrate with various dimensions and materials positioned in the assembly, thereby preventing substrate improper positioning, misalignment, and substrate lean.

While the foregoing is directed to embodiments of the present invention, other and further embodiments of the invention may be devised without departing from the basic scope thereof, and the scope thereof is determined by the claims that follow.

What is claimed:

1. A compliant substrate holding assembly comprising:
a base plate;
two arms disposed on opposite ends of the base plate and each arm having a substrate receiving slot; and
a resilient finger disposed on the base plate between the arms and having a substrate receiving slot, wherein the slots define a first substrate holding position.

2. The apparatus of claim 1, further comprising:
a sensor disposed on the base plate and arranged to detect a metric indicative of a change in finger position.

3. The apparatus of claim 2, wherein further comprising:
a tip of the finger adapted to interface with the sensor.

4. The apparatus of claim 3, further comprising:
a notch formed in the sensor and configured to allow the tip to pass therethrough.

5. The apparatus of claim 1, wherein the base plate further comprises:
a first step formed on an upper surface of a first end of the base plate.

6. The apparatus of claim 5, wherein the finger further comprises:
a body coupled to the first step.

7. The apparatus of claim 1, wherein the finger is coupled to the base plate in a cantilevered orientation.

8. The apparatus of claim 1 further comprises a second resilient finger disposed between the arms, the second resilient finger and the arms having three slots defining a second substrate holding position.

9. The apparatus of claim 8 further comprising:
a second sensor arranged to detect a metric indicative of a change in a position of the second finger.

10. The apparatus of claim 8, wherein the fingers extend cantilevered from a common body coupled to the base plate.

11. The apparatus of claim 1, wherein the complaint substrate holding assembly is grounded.

12. A compliant substrate holding assembly comprising:
at least a pair of opposing substrate receiving structures;
a substrate supporting structure disposed between the pair of receiving structures, the substrate supporting structure biased to a first position; and
a sensor arranged to detect a change in position of the substrate supporting structure when a substrate is positioned in the pair of receiving structures and on the supporting structure.

13. The apparatus of claim 12, wherein the substrate supporting structure further comprises:
a body coupled to the base plate;
a first finger extending cantilevered from the body; and
a substrate receiving slot formed on the finger.

14. The apparatus of claim 13, wherein a substrate receiving slot is V-shaped.

15. The apparatus of claim 13, wherein the finger has a first position above the sensor.

16. The apparatus of claim 15, further comprising:
a second finger extending from the body substantially parallel to the first finger.

17. The apparatus of claim 16 further comprising:
a second sensor disposed at a location to engage the second finger.

18. A compliant substrate holding assembly comprising:
a base plate having at least two arms extending upward from opposite sides of the base plate, each arm having at least one V-shaped substrate receiving structure;
a resilient finger having a V-shaped substrate receiving structure disposed between the arms; and
a sensor arranged to detect a change in position of the finger.

19. The apparatus of claim 18, further comprising:
a step formed on a first end of the base plate and defining a gap between the finger and base plate.

20. The apparatus of claim 18, wherein the substrate receiving structures are V-shaped.

21. A method for holding a substrate on a compliant substrate holding assembly, comprising:
inserting a substrate in a holding assembly having at least three substrate supporting structures; and
detecting a change in position of one of the substrate supporting structures.

22. The method of claim 21, wherein the step of inserting the substrate further comprises:
deflecting a cantilevered finger.

23. The method of claim 22, wherein deflecting further comprises:
moving a tip of the finger through a region that causes a sensor to change state.

24. The method of claim 22, wherein the deflection of the finger is caused by the weight of the inserted substrate.
